(19) United States
(12) Patent Application Publication
(10) Pub. No.: US 2002/0149421 A1
(43) Pub. Date: Oct. 17, 2002

(54) Device and method for demodulating frequency-modulated signals

(76) Inventors: Stefan Waasen, Duisburg (DE); Giuseppe Li Puma, Bochum (DE)

Correspondence Address: LERNER AND GREENBERG, P.A., POST OFFICE BOX 2480, HOLLYWOOD, FL, 33022-2480, US

(21) Appl. No.: 10/036,033

(22) Filed: Jan. 4, 2002

(30) Foreign Application Priority Data
Jun. 30, 1999 (DE) 199 30 227.8
May 25, 2000 (DE) PCT/DE00/01687

(51) Int. Cl. H03D 3/00

(52) U.S. Cl. 329/315

(57) ABSTRACT

A demodulator characteristic curve is oriented centrosymmetrically with respect to the intermediate frequency using a polyphase filter. In this way, the signals can be demodulated with minimal cost and with an optimal result.

### CROSS-REFERENCE TO RELATED APPLICATION

This application is a continuation of copending International Application No. PCT/DE00/01687, filed May 25, 2000, which designated the United States.

### BACKGROUND OF THE INVENTION

1. Field of the Invention

The present invention relates to a device and to a method for demodulating a frequency-modulated signal, in which the frequency-modulated signal is converted into orthogonal components at an intermediate frequency.

A device and a method of this type are used, for example, in the demodulation of a frequency-modulated signal using the so-called quadricorrelator construction mode.

The basic construction of a quadricorrelator is illustrated in FIG. 3. A comparable demodulator circuit is shown in GB 1 530 602. The quadricorrelator shown in FIG. 3 includes a first mixer M1, a second mixer M2, a first low-pass filter TP1, a second low-pass filter TP2, a first differentiating element D1, a second differentiating element D2, a first multiplier X1, a second multiplier X2, and a subtractor S. The signal to be demodulated is designated by E(t), and the demodulated signal is designated by A(t).

The first mixer M1 and the low-pass filter TP1 connected downstream thereof, convert the signal E(t), which is to be demodulated, into a signal I(t) with a predetermined intermediate frequency. The first mixer M1 multiplies the signal E(t) by cos (ω₀t), and the low-pass filter TP1 filters out the components of the result which were produced during the mixing, but which are unnecessary or disturbing for further processing. The signal I(t) is differentiated by the first differentiator D1, thereby producing a differentiated signal I′(t).

The second mixer M2 and the low-pass filter TP2 connected downstream thereof, convert the signal E(t), which is to be demodulated, into a signal Q(t) with a predetermined intermediate frequency. The signals I(t) and Q(t) are mutually orthogonal signal components. I(t) is referred to as the in-phase component, and Q(t) is referred to as the quadrature component. In this case, the second mixer M2 multiplies the signal E(t) by −sin(ω₀t), and the low-pass filter TP2 filters out the components of the result which were produced during the mixing, but which are unnecessary or disturbing for further processing. The signal Q(t) is differentiated by the second differentiator, thereby producing a differentiated signal Q′(t).

The first multiplier X1 multiplies the signal I′(t) by the signal Q(t).

The second multiplier X2 multiplies the signal Q′(t) by the signal I(t).

The output signals of the multipliers X1 and X2 are fed to the subtractor S. The subtractor S forms the difference I′(t)·Q(t)−I(t)·Q′(t) and outputs this as the demodulated signal A(t).

With regard to further details on the construction, function and mode of operation of quadricorrelators, reference can be made to Floyd M. Gardner: Characteristics of Frequency-Tracking Loops in: Phase-Locked Loops, Editors: W. C. Lindsey, C. M. Chie, New York, IEEE Press, 1986, pages 226 to 240.

Quadricorrelators are often used when using so-called low IF structures (when using low intermediate frequencies). In this case, the differentiating elements are usually realized by high-pass or low-pass filters.

Purely theoretically, demodulating frequency-modulated signals using a quadricorrelator leads to outstanding results with a comparatively low cost. In practice, however, diverse problems occasionally arise. The demodulated signal may have non-linearities in the frequency range (high frequencies are occasionally weighted differently than low frequencies), may have severe and/or non-uniformly distributed noise, and/or may require subsequent offset correction. These problems can be prevented or eliminated only with a relatively high cost—if at all.

Published German Patent Application DE 197 38 363 A1 describes a receiver for mobile radio systems in which quadrature components are filtered using a polyphase filter, are then amplified in an AGC (Automatic Gain Control) stage, and are then demodulated. The demodulator includes respective mixers to which a respective output signal component of the AGC stage is fed directly. Utilizing cross-coupling, the mixers also receive the other output signal component of the AGC stage in a differentiated manner. The demodulated output signal is obtained by subtractive superposition of the output signals of the mixers.

U.S. Pat. No. 4,342,000 shows a detector for frequency-modulated signals. The detector contains a mixer that directly receives input signal components and input signal components from a phase shifting element. With regard to a transfer characteristic curve of the circuit, symmetries with respect to an intermediate frequency are present for phase shift and differential gain.

European Patent Application EP 0 797 292 A shows a receiver circuit in which the input signal is converted into orthogonal components. The orthogonal components are capacitively coupled to a polyphase filter. The outputs of the polyphase filter are fed into an equalizer.

### SUMMARY OF THE INVENTION

It is accordingly an object of the invention to provide a device for demodulating a frequency-modulated signal and a method for demodulating a frequency-modulated signal which overcomes the above-mentioned disadvantages of the prior art apparatus and methods of this general type.

In particular, it is an object of the invention to demodulate signals with a minimal outlay of components and to achieve results that satisfy even extremely stringent requirements.

With the foregoing and other objects in view there is provided, in accordance with the invention, a device for demodulating a frequency-modulated signal. The device includes mixers for converting a frequency-modulated signal into mutually orthogonal components at an intermediate frequency. The orthogonal components define a first component and a second component. The device includes a polyphase filter having inputs receiving the first component and the second component. The polyphase filter filters the first component to obtain a first output signal. The polyphase filter filters the second component to obtain a second output signal. The device includes an additional mixer having an input receiving the first component and another input receiving the second output signal. The device also includes an additional mixer having an input receiving the second component and another input receiving the first output signal.

In accordance with an added feature of the invention, the polyphase filter has a pass-band that is oriented symmetrically with respect to the intermediate frequency.

In accordance with an additional feature of the invention, the polyphase filter includes: a first low-pass filter having an input and an output; and the first amplifier having an input connected to the output of the first low-pass filter. The first amplifier has an output. The polyphase filter also includes: a second low-pass filter having an input and an output; and a second amplifier having an input connected to the output of the second low-pass filter. The second amplifier has an output. The polyphase filter also includes a first adder having an input receiving the first component. The first adder has another input connected to the output of the second amplifier. The polyphase filter also includes a second adder having an input receiving the second component. The second adder has another input connected to the output of the first amplifier.

In accordance with another feature of the invention: the first low-pass filter has a cut-off frequency; the second low-pass filter has a cut-off frequency; the first amplifier has a gain factor set to a value formed from a quotient of the intermediate frequency and the cut-off frequency of the first low-pass filter; and the second amplifier has a gain factor set to a value formed from a quotient of the intermediate frequency and the cut-off frequency of the second low-pass filter.

With the foregoing and other objects in view there is also provided, in accordance with the invention, a method for demodulating a frequency-modulated signal. The method includes the following steps: converting a frequency-modulated signal into mutually orthogonal components at a predetermined intermediate frequency; demodulating the orthogonal components with a demodulator having a demodulator characteristic curve; orienting the demodulator characteristic curve centrosymmetrically with respect to the intermediate frequency by polyphase filtering the orthogonal components and thereby obtaining polyphase filtered signals; and for each one of the orthogonal components, mixing the one of the orthogonal components with the one of the polyphase-filtered signals that is obtained from the other one of the orthogonal components.

In accordance with an important feature of the invention: a polyphase filter and mixers are used, the demodulator characteristic curve is oriented centrosymmetrically with respect to the intermediate frequency.

Devices and methods of this type enable the measures that are performed for demodulation to be effected symmetrically with respect to the intermediate frequency. By eliminating the asymmetries present in conventional demodulators, many advantages are obtained:

(high and low) frequencies lying above and below the intermediate frequency are rated identically;

the noise is band-limited to a greater extent and is distributed more uniformly in the frequency range of interest;

the nonlinearities that may be present act on the high and the low frequencies equally, as a result of which they are no longer as critical; and

offset correction is no longer necessary.

Devices and methods of the type claimed thus enable signals to be demodulated with minimal outlay and with an optimal result.

Other features which are considered as characteristic for the invention are set forth in the appended claims.

Although the invention is illustrated and described herein as embodied in a device and method for demodulating frequency-modulated signals, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 shows an inventive device for demodulating frequency-modulated signals;

FIG. 2 shows a polyphase filter contained in the device shown in FIG. 1; and

FIG. 3 shows a prior art device for demodulating frequency-modulated signals.

### DESCRIPTION OF THE PREFERRED EMBODIMENTS

In the example considered, the device and the method for demodulating frequency-modulated signals are used in a system operating according to the DECT standard. However, it is pointed out that there is no restriction to the DECT standard. The device and the method described can also be used in any other system desired.

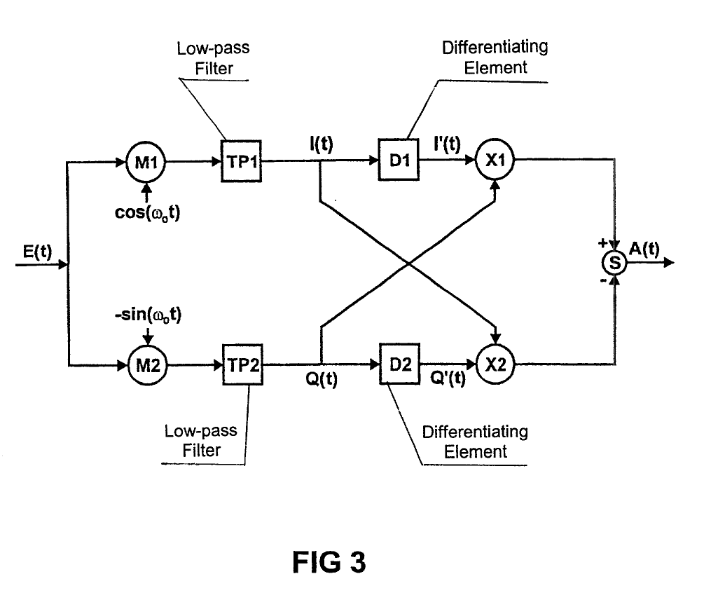

The device described is a novel practical realization of the quadricorrelator shown in FIG. 3. Unlike the circuit shown in FIG. 3, the differentiating elements D1 and D2 are not realized by high-pass filters or low-pass filters. Instead, a polyphase filter is used, with one pole of the polyphase filter being considered.

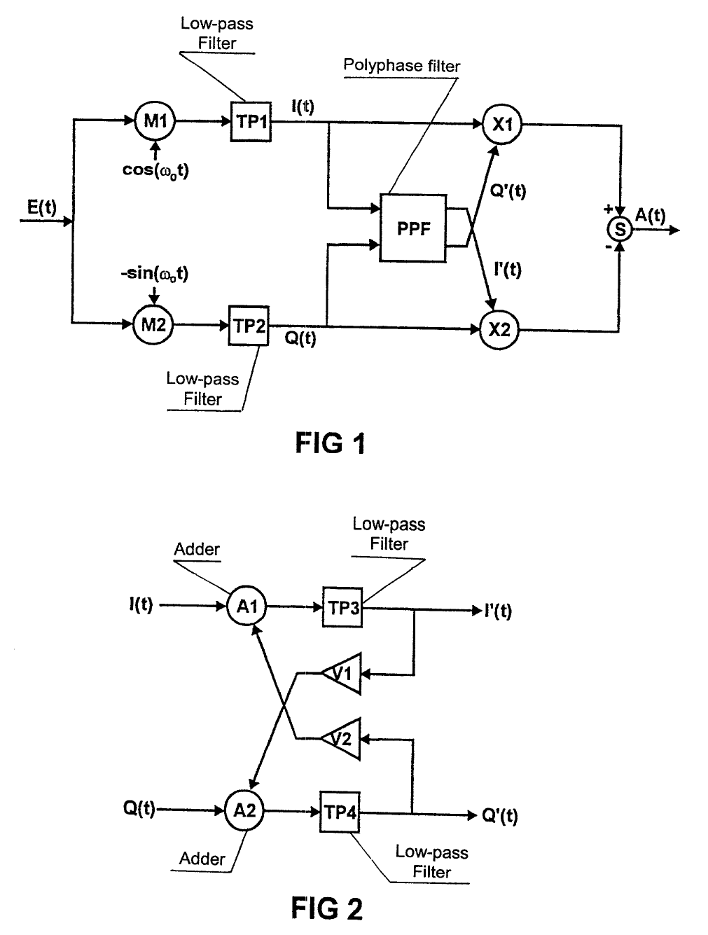

The novel demodulator is illustrated in FIG. 1.

By comparing FIGS. 1 and 3 it can be seen that the basic structure of the quadricorrelator shown in FIG. 3 is preserved in the novel demodulator. Elements that are designated by the same reference symbols correspond to one another and are not described again to avoid repetition. What is new about the demodulator shown in FIG. 1 is that the differentiating elements D1 and D2 are omitted and the polyphase filter already mentioned is used. The polyphase filter is designated by the reference symbol PPF in FIG. 1.

As can be seen from FIG. 1, the polyphase filter PPF receives the mutually orthogonal signals I(t) and Q(t) (still present) and generates the signals I′(t) and Q′(t) from them. The signals I′(t) and Q′(t) are differentiated with respect to time. These signals are multiplied by Q(t) and I(t) respectively, by the multipliers X1 and X2 (still present), and are subtracted from one another by the subtractor S (still present). The (demodulated) signal A(t) output from the demodulator according to FIG. 1 is thus I′(t)·Q(t)−I(t)·Q′(t) as in the case of the quadricorrelator shown in FIG. 3.

The construction of the polyphase filter PPF is shown in FIG. 2. In the example considered, it contains a first adder A1, a second adder A2, a first low-pass filter TP3, a second low-pass filter TP4, a first amplifier V1, and a second amplifier V2.

The signal I(t) is input into the polyphase filter PPF and is added by the first adder A1 to the signal that has been output from the second low-pass filter TP4 and that has been amplified by the second amplifier V2. The signal resulting from the addition is then subjected to low-pass filtering by the first low-pass filter TP3. The signal output from the first low-pass filter TP3 is the signal I′(t).

The signal Q(t) is input into the polyphase filter PPF and is added by the second adder A2 to the signal that has been output from the first low-pass filter TP3 and that has been amplified by the first amplifier V1. The signal resulting from the addition is then subjected to low-pass filtering by the second low-pass filter TP1. The signal output from the second low-pass filter TP4 is the signal Q′(t).

The polyphase filter PPF does not actually carry out differentiation of the signals I(t) and Q(t). However, in the range that is of interest in the present case, the signals I(t) and Q(t) that are output correspond to the result of differentiation with sufficient accuracy.

The polyphase filter PPF actually only performs low-pass filtering. However, the center frequency of the transmission curve of the filter can be shifted by the gain factors (designated by k below) of the amplifiers V1 and V2.

In a normal low-pass filter, the center frequency of the transmission curve is 0 Hz, and the transmission curve runs centrosymmetrically with respect to this zero point. This also applies to the low-pass filters TP3 and TP4 contained in the polyphase filter PPF. However, their transmission curves can be shifted as a result of the cross coupling (the coupling-in of the output signal of TP3 at the input of TP4, and the coupling-in of the output signal of TP4 at the input of TP3), in a manner dependent on the gain factors k of the amplifiers V1 and V2 that are provided in the cross-coupling paths.

In the example considered,, the center frequencies of the transmission curves of the low-pass filters are shifted in such that they are situated at the intermediate frequency to which the signal E(t) to be demodulated was converted by the mixers M1 and M2.

This can be achieved by setting the gain factors k of the amplifiers V1 and V2 to ZF/ω₀ where ZF designates the intermediate frequency and where ω₀ designates the cut-off frequency of the low-pass filters. As a result, if 1/(1+jω/ω₀) is used as the transfer function of the low-pass filters TP3 and TP4, the following demodulator characteristic curve is obtained:

$$D = - \frac{( ω - k \cdot {ω}_{0} ) / {ω}_{0}}{1 + {( ( ω - k \cdot {ω}_{0} ) / {ω}_{0} )}^{2}}$$

This characteristic curve is centrosymmetrical with respect to the intermediate frequency (k·ω₀).

With regard to further details on the construction, operation, function, and mode of operation of polyphase filters, reference is made to M. Steyaert, J. Crols: Analog Integrated Polyphase Filters, in: Analog Circuit Design, Editors: W. Sansen, J. H. Huijsing, R. J. Van de Plassche, Boston, Kluwer Academic Publishers, 1994, Vol. 3, pages 149-166.

The centrosymmetrical orientation of the demodulator characteristic curve with respect to the intermediate frequency provides the following advantages:

(high and low) frequencies lying above and below the intermediate frequency are rated identically;

the noise is band-limited to a greater extent and is distributed more uniformly in the frequency range of interest;

nonlinearities that may be present act on the high and the low frequences equally, as a result of which they are no longer as critical; and

offset correction is no longer necessary (the demodulator yields the value zero at the center frequency (the intermediate frequency)).

Consequently, the device and the method described enable signals to be demodulated with minimal cost and with an optimal result.

We claim:

1. A device for demodulating a frequency-modulated signal, comprising:
mixers for converting a frequency-modulated signal into mutually orthogonal components at an intermediate frequency, the orthogonal components defining a first component and a second component;
a polyphase filter having inputs receiving the first component and the second component, said polyphase filter filtering the first component to obtain a first output signal, said polyphase filter filtering the second component to obtain a second output signal;
an additional mixer having an input receiving the first component and another input receiving the second output signal; and
an additional mixer having an input receiving the second component and another input receiving the first output signal.

2. The device according to claim 1, wherein said polyphase filter has a pass-band that is oriented symmetrically with respect to the intermediate frequency.

3. The device according to claim 1, wherein said polyphase filter includes:
a first low-pass filter having an input and an output;
a first amplifier having an input connected to said output of said first low-pass filter, said first amplifier having an output;
a second low-pass filter having an input and an output;
a second amplifier having an input connected to said output of said second low-pass filter, said second amplifier having an output;
a first adder having an input receiving the first component, said first adder having another input connected to said output of said second amplifier; and
a second adder having an input receiving the second component, said second adder having another input connected to said output of said first amplifier.

4. The device according to claim 3, wherein:
said first low-pass filter has a cut-off frequency;
said second low-pass filter has a cut-off frequency;
said first amplifier has a gain factor set to a value formed from a quotient of the intermediate frequency and the cut-off frequency of said first low-pass filter; and
said second amplifier has a gain factor set to a value formed from a quotient of the intermediate frequency and the cut-off frequency of said second low-pass filter.

5. A method for demodulating a frequency-modulated signal, which comprises:
converting a frequency-modulated signal into mutually orthogonal components at a predetermined intermediate frequency;
demodulating the orthogonal components with a demodulator having a demodulator characteristic curve;
orienting the demodulator characteristic curve centrosymmetrically with respect to the intermediate frequency by polyphase filtering the orthogonal components and thereby obtaining polyphase filtered signals; and
for each one of the orthogonal components, mixing the one of the orthogonal components with the one of the polyphase-filtered signals that is obtained from the other one of the orthogonal components.
